(19) United States
(12) Patent Application Publication
(10) Pub. No.: US 2026/0343758 A1
(43) Pub. Date: Oct. 29, 2026

(54) DISPLAY APPARATUS AND WEARABLE DEVICE

(71) Applicant: BOE Technology Group Co., Ltd., Beijing (CN)

(72) Inventors: Youqing SHEN, Beijing (CN); Hong ZHU, Beijing (CN); Chao SUN, Beijing (CN)

(73) Assignee: BOE Technology Group Co., Ltd., Beijing (CN)

(21) Appl. No.: 18/841,406

(22) PCT Filed: Dec. 15, 2023
(86) PCT No.: PCT/CN2023/139188

§ 371 Date: Aug. 26, 2024

(51) Int. Cl. H05K 5/02; G04G 17/02

(52) U.S. Cl. CPC H05K 5/0226; G04G 17/02

(57) ABSTRACT

Provided is a display apparatus. The display apparatus includes: a body support assembly, two rotatable support assemblies, a hinge, and a flexible display panel. At least two reversible assemblies in the hinge are disposed on two sides of the support base and are connected to the support base, wherein one reversible assembly is rotationally connected to the body support assembly, and another reversible assembly is rotationally connected to the rotatable support assembly. When the display apparatus is switched between the unfolded state and the folded state, the hinge can rotate at a certain angle relative to the body support assembly under the action of an external force, and the rotatable support assembly can also rotate at a certain angle relative to the hinge

### CROSS-REFERENCE TO RELATED APPLICATION

This application is a U.S. national phase application based on PCT/CN2023/139188, filed on Dec. 15, 2023, the content of which is incorporated herein by reference in its entirety.

### TECHNICAL FIELD

The present disclosure relates to the field of display technologies, and in particular, relates to a display apparatus and a wearable device.

### BACKGROUND

With the development of display technology, more and more display apparatuses (e.g., smartwatches) are equipped with a foldable display screen. A display apparatus having a foldable display screen can realize the switching of the physical size of the display apparatus, which greatly improves user experience.

### SUMMARY

Embodiments of the present disclosure provide a display apparatus and a wearable. Technical solutions are described as follows.

In one aspect, a display apparatus is provided. The display apparatus includes:
a body support assembly;
two rotatable support assemblies disposed on two sides of the body support assembly in a first direction;
a hinge disposed between the body support assembly and the rotatable support assembly in the first direction, wherein the hinge includes a support base and at least two flip assemblies, wherein the support base extends along a second direction intersected with the first direction; and the at least two flip assemblies are oppositely disposed in the first direction and are both connected to the support base, one of the at least two flip assemblies is connected to the body support assembly, and another of the at least two flip assemblies is connected to the rotatable support assembly; and
a flexible display panel, wherein a rear surface of the flexible display panel is connected to the body support assembly, the support base, and the rotatable support assemblies.

In some embodiments, each of the at least two flip assemblies includes a rotating arm, wherein a first end of the rotating arm is fixedly connected to the support base, and a second end of the rotating arm is rotatably connected to a target support assembly, the target support assembly being the body support assembly or the rotatable support assembly.

In some embodiments, the rotating arm is an arc-shaped slide plate, and a first arc-shaped chute matched with the arc-shaped slide plate is arranged in a side, facing towards the support base, of the target support assembly, at least a portion of the arc-shaped slide plate being disposed in and rotatably connected to the first arc-shaped chute.

In some embodiments, the target support assembly includes a support portion and a first connection block; wherein
a mounting groove is arranged in a side, close to the support base, of the support portion; and
the first connection block is secured in the mounting groove, the first arc-shaped chute is arranged in a side, facing towards the rotating arm, of the first connection block, and a surface of the first connection block facing towards the flexible display panel is flush with a surface of the support portion facing towards the flexible display panel;
wherein a strength of the first connection block is greater than a strength of the support portion.

In some embodiments, a first positioning member is arranged on a surface, facing towards the support base, in an inner wall of the mounting groove, and a through hole is arranged in a surface, facing towards the flexible display panel, in the inner wall of the mounting groove;
a second positioning member clamped with the first positioning member and a connection hole in communication with the through hole are arranged on the first connection block, the connection hole being closer to the flexible display panel than the through hole to the flexible display panel; and
the target support assembly further includes a fastener, an end of the fastener being fastened to the connection hole upon passing through the through hole.

In some embodiments, a chute opening allowing the arc-shaped slide plate to slide into and a limit blind end opposite to the chute opening are arranged in the first arc-shaped chute, and a first limit protrusion is arranged on an inner wall of the first arc-shaped chute; and
a second limit protrusion matched with the first limit protrusion is arranged at an end portion of the arc-shaped slide plate;
wherein in a case that the display apparatus is in a folded state, the end portion of the arc-shaped slide plate is abutted against the limit blind end of the first arc-shaped chute; and in a case that the display apparatus is in an unfolded state, the first limit protrusion is abutted against the second limit protrusion.

In some embodiments, each of the at least two flip assemblies further includes a drive rod and a first protrusion portion, wherein one end of the drive rod is rotatably connected to the support base, and another end of the drive rod is fixedly connected to the first protrusion portion; and
a linear chute is arranged in a side, facing towards the support base, of the target support assembly, the another end of the drive rod extends into the linear chute, and the first protrusion portion is capable of sliding within the linear chute relative to the target support assembly.

In some embodiments, the hinge further includes two connection shafts corresponding to two flip assemblies opposite to each other, wherein the two connection shafts are secured in the support base, and an end of the drive rod in the flip assembly is sleeved on and rotatably connected to a corresponding connection shaft.

In some embodiments, a plurality of synchronizing external teeth are arranged at an end, facing away from the first protrusion portion, of the drive rod;
wherein two drive rods in the two flip assemblies opposite to each other are meshed via the synchronizing external teeth.

In some embodiments, the hinge further includes a torsion mechanism connected to the two connection shafts, the torsion mechanism being configured to provide a damping force in a case that the target support assembly is rotated relative to the support base.

In some embodiments, the torsion mechanism includes a torsion member and an elastic element sleeved on each of the two connection shafts, wherein the torsion member is abutted against a portion, sleeved on the connection shaft, of the drive rod, and the elastic element is disposed on a side, facing away from the drive rod, of the torsion member;
wherein two torsion members sleeved on the two connection shafts are fixedly connected.

In some embodiments, a plurality of first abutment portions are arranged on a side facing towards the torsion member of the portion, sleeved on the connection shaft, of the drive rod, and a plurality of second abutment portions are arranged on a side, facing towards the drive rod, of the torsion member.

In some embodiments, the torsion mechanism further includes an auxiliary torsion member sleeved on each of the connection shafts, wherein the auxiliary torsion member is disposed on a side, facing away from the torsion member, of the drive rod, and the auxiliary torsion member is abutted against the portion, sleeved on the connection shaft, of the drive rod;
wherein two auxiliary torsion members sleeved on the two connection shafts are fixedly connected.

In some embodiments, the support base is provided with a first limit plate and a second limit plate opposite to each other, and two ends of the connection shaft respectively are connected to the first limit plate and the second limit plate, the auxiliary torsion member, the drive rod, the torsion member, and the elastic element are sequentially arranged between the first limit plate and the second limit plate, and an end, facing away from the torsion member, of the elastic element is abutted against the second limit plate.

In some embodiments, the hinge further includes a protective member movably connected to a side, facing away from the flexible display panel, of the support base, wherein the protective member is used to cover at least a portion of the flip assembly, is slidably connected to the body support assembly and the rotatable support assembly, and the protective member is configured to move along a direction away from the support base during switching of the display apparatus from an unfolded state to a folded state, and to move along a direction close to the support base during switching of the display apparatus from a folded state to the unfolded state.

In some embodiments, the target support assembly includes a support portion and a second connection block, wherein the second connection block is fixedly connected to a side, facing away from the flexible display panel, of the support portion, and a second arc-shaped chute is arranged in a side of the second connection block; and
the protective member includes: a protective plate, an extension portion secured to a side, facing towards the support base, of the protective plate, and a rotating plate fixedly connected to a side, facing away from the protective plate, of the extension portion, wherein a second protrusion portion matched with the second arc-shaped chute is arranged on the rotating plate, and the second protrusion portion is slidably connected to the second connection block within the second arc-shaped chute.

In some embodiments, the target support assembly includes two second connection blocks, wherein the rotating plate is disposed between the two second connection blocks, two second protrusion portions opposite to each other are arranged on the rotating plate, and the two second protrusions portions are respectively disposed in the two second arc-shaped chutes of the two second protrusion blocks.

In some embodiments, the protective member further includes a first guide member fixedly connected to a side, facing away from the protective plate, of the extension portion, and a second guide member is arranged on a side, facing towards the protective plate, of the support base;
wherein a blind hole is arranged in one of the first guide member and the second guide member, and another of the first guide member and the second guide member is capable of extending into the blind hole and is capable of sliding within the blind hole.

In some embodiments, the hinge further includes two protective side plates connected to two ends of the support base, wherein the support base is disposed between the two protective side plates in the second direction; and
an avoidance groove matched with the protective side plates is arranged in a side surface of the target support assembly.

In another aspect, a wearable device is provided. The wearable device includes:
a display apparatus and a watchband detachably connected to the display apparatus, wherein the display apparatus is the display apparatus according to any one of the foregoing aspect.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a display apparatus according to some embodiments of the present disclosure;

FIG. 2 is a partial schematic structural diagram of the display apparatus shown in FIG. 1;

FIG. 3 is a schematic effect diagram of switching between an unfolded state and a folded state according to some embodiments of the present disclosure;

FIG. 4 is a partial schematic structural diagram of a display apparatus according to some embodiments of the present disclosure;

FIG. 5 is a partial structural sectional view of a display apparatus;

FIG. 6 is a partial structural exploded schematic diagram of a display apparatus according to some embodiments of the present disclosure;

FIG. 7 is a partial schematic structural diagram of another display apparatus according to some embodiments of the present disclosure;

FIG. 8 is a cross-sectional view of another display apparatus according to some embodiments of the present disclosure;

FIG. 9 is a schematic effect diagram of a display apparatus in a folded state according to some embodiments of the present disclosure;

FIG. 10 is a partial exploded schematic structural diagram of another display apparatus according to some embodiments of the present disclosure;

FIG. 11 is a partial exploded schematic diagram of a portion of the structure of yet another display apparatus according to some embodiments of the present disclosure;

FIG. 12 is a partial schematic structural diagram of yet another display apparatus according to some embodiments of the present disclosure;

FIG. 13 is a schematic effect diagram of switching between an unfolded state and a folded state of a display apparatus according to some embodiments of the present disclosure;

FIG. 14 is a schematic structural diagram of a protective member according to some embodiments of the present disclosure;

FIG. 15 is a schematic structural diagram of a support base according to some embodiments of the present disclosure;

FIG. 16 is a side schematic diagram of a display apparatus when a flexible display panel is unfolded according to some embodiments of the present disclosure;

FIG. 17 is a schematic diagram of a membrane layer structure of a flexible display panel according to some embodiments of the present disclosure;

FIG. 18 is an exploded schematic diagram of a display apparatus according to some embodiments of the present disclosure; and

FIG. 19 is a schematic structural diagram of a wearable device according to some embodiments of the present disclosure.

The above drawings have shown the explicit embodiments of the present disclosure, which will be described below in detail. These drawings and text descriptions are not intended to limit the scope of the conception of the present disclosure in any way, but to illustrate the concept of the present disclosure to those skilled in the art with reference to specific embodiments.

### DETAILED DESCRIPTION

For clearer descriptions of the objectives, technical solutions, and advantages of the present disclosure, embodiments of the present disclosure are described in detail hereinafter with reference to the accompanying drawings.

In the related art, the current display apparatus equipped with a foldable display screen supports a single folding pattern, resulting in poor flexibility in the use of the display apparatus. The present disclosure provides a display apparatus, which can solve the problem that the display apparatus equipped with a foldable display screen supports a relatively single folding pattern.

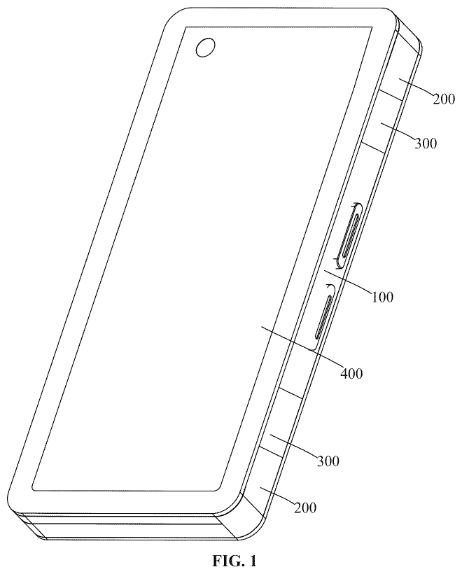

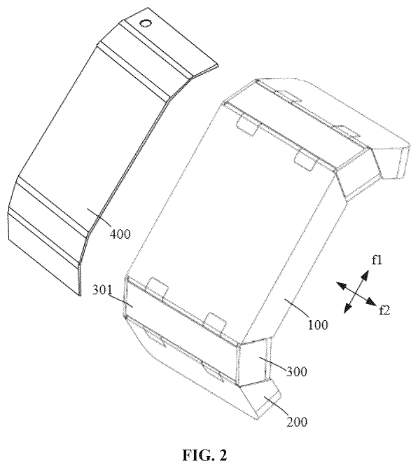

Referring to FIGS. 1 and 2, FIG. 1 is a schematic structural diagram of a display apparatus according to some embodiments of the present disclosure, and FIG. 2 is a partial schematic structural diagram of the display apparatus shown in FIG. 1. The display apparatus is any product with a display function, such as a mobile phone, a tablet computer, a television, a display, a notebook computer, a digital photo frame, and a navigator, or a device body in a wearable device. The display apparatus may include: a body support assembly 100, two rotatable support assemblies 200, a hinge 300, and a flexible display panel 400.

The two rotatable support assemblies 200 in the display apparatus may be disposed on two sides of the body support assembly 100 in a first direction f1.

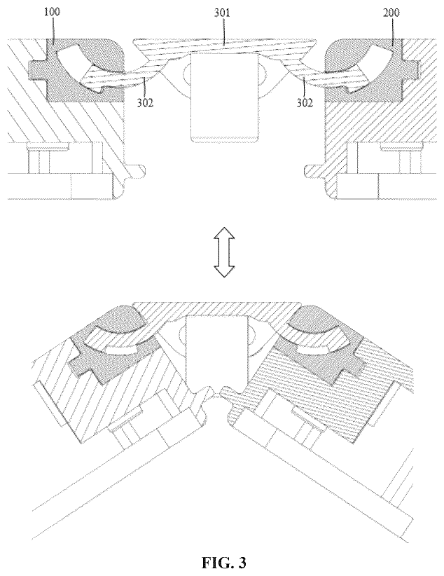

The hinge 300 in the display apparatus may be disposed between the body support assembly 100 and the rotatable support assembly 200 in the first direction f1, i.e., there may be one hinge 300 disposed between each rotatable support assembly 200 and the body support assembly 100. Referring to FIG. 3, FIG. 3 is a schematic effect diagram of switching between an unfolded state and a folded state according to some embodiments of the present disclosure. The hinge 300 may include: a support base 301 and at least two flip assemblies 302, the support base 301 may extend along a second direction f2 (e.g., the first direction may be perpendicular to the second direction) intersected with the first direction f1. At least two flip assemblies 302 are oppositely disposed in the first direction f1 and are both connected to the support base 301, one of the at least two flip assemblies 302 may be connected to the body support assembly 100, and another of the at least two flip assemblies may be connected to the rotatable support assembly 200. Exemplarily, the hinge 300 may include four flip assemblies 302, wherein two of the flip assemblies 302 are disposed along the first direction f1 on one side of the support base 301 and are both connected to the support base 301 and the body support assembly 100, and the other two flip assemblies 302 are disposed on the other side of the support base 301 and are both connected to the support base 301 and the rotatable support assembly 200.

The rear surface of the flexible display panel 400 in the display apparatus may be fixedly connected to the body support assembly 100, the support base 301, and the rotatable support assemblies 200, respectively. It should be noted that the rear surface of the flexible display panel 400 is a surface opposite to the display side of the flexible display panel 400.

In the embodiments of the present disclosure, by providing the hinge 300 between the body support assembly 100 and the rotatable support assembly 200 in the display apparatus, at least two flip assemblies 302 in the hinge 300 are disposed on two sides of the support base 301 and connected to the support base 301, wherein one flip assembly 302 can be rotatably connected to the body support assembly 100, and another flip assembly 302 can be rotatably connected to the rotatable support assembly 200. When the display apparatus is switched between the unfolded state and the folded state, the hinge 300 can rotate at a certain angle relative to the body support assembly 100 under the action of an external force, and the rotatable support assembly 200 can also rotate at a certain angle relative to the hinge 300. In this case, the flexible display panel 400 can also be folded into different patterns under the drive of the hinge 300 and the rotatable support assembly 200, such that the display apparatus provided with the flexible display panel 400 in the present disclosure supports various different folding patterns, which improves the flexibility in use of the display apparatus, and improves user experience. Here, in the process of switching between the unfolded state and the folded state of the display apparatus, the angle at which the hinge 300 rotates relative to the body support assembly 100 and the angle at which the rotatable support assembly 200 rotates relative to the hinge 300 may both be acute angles.

Exemplarily, referring to FIG. 3, when the display apparatus is in the unfolded state, the side, facing towards the flexible display panel 400, of the body support assembly 100, the side, facing towards the flexible display panel 400, of the support base 301 in the hinge 300, and the side, facing towards the flexible display panel 400, of the rotatable support assembly 200 may be flush. When the display apparatus is switched from the unfolded state to the folded state, the hinge 300 and the rotatable support assembly 200 disposed on one side of the body support assembly 100 are illustrated schematically as an example: the direction in which the hinge 300 is rotated relative to the body support assembly 100 by the flip assembly 302 may be in the same direction as the direction in which the rotatable support assembly 200 is rotated relative to the hinge 300 by the flip assembly 302. It should be noted that the basic structural composition and movement principle of the rotatable support assembly 200 and the hinge 300, which are disposed on opposite sides of the body support assembly 100, are the same, and can be referred to as described in the above, and will not be repeated herein.

In summary, the embodiments of the present disclosure provide a display apparatus that may include: a body support assembly, two rotatable support assemblies, a hinge, and a flexible display panel. By providing the hinge between the body support assembly and the rotatable support assembly in the display apparatus, at least two flip assemblies in the hinge are disposed on two sides of the support base and are connected to the support base, wherein one flip assembly is rotatably connected to the body support assembly, and another flip assembly is rotatably connected to the rotatable support assembly. When the display apparatus is switched between the unfolded state and the folded state, the hinge can rotate at a certain angle relative to the body support assembly under the action of an external force, and the rotatable support assembly can also rotate at a certain angle relative to the hinge. In this case, the flexible display panel can also be folded into different patterns under the drive of the hinge and the rotatable support assembly, such that the display apparatus provided with the flexible display panel in the present disclosure supports various different folding patterns, which improves the flexibility in use of the display apparatus, and improves user experience.

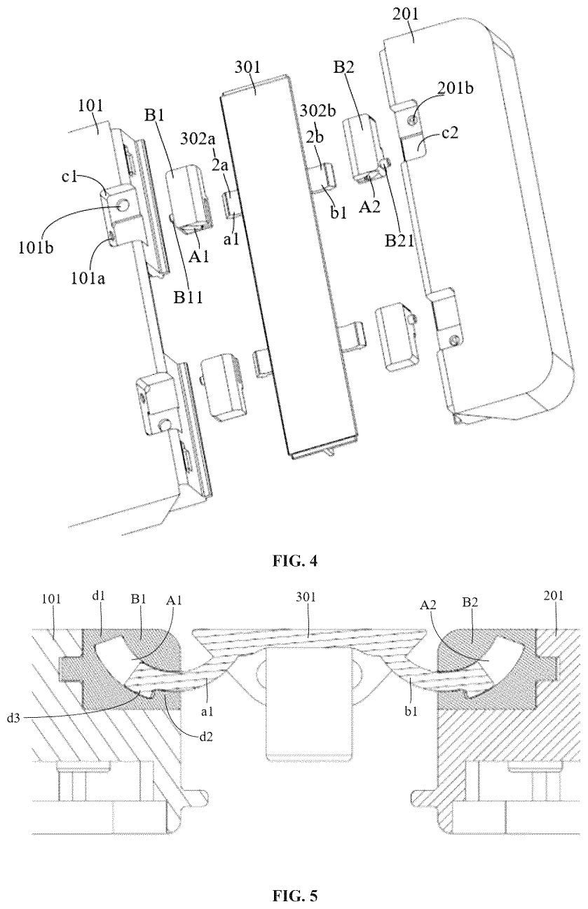

Optionally, referring to FIGS. 4 and 5, FIG. 4 is a partial schematic structural diagram of a display apparatus according to some embodiments of the present disclosure, and FIG. 5 is a partial structural sectional view of a display apparatus. Each of the at least two flip assemblies 302 in the hinge 300 may include: a rotating arm. A first end of the rotating arm may be fixedly connected to the support base 301, and a second end of the rotating arm may be rotatably connected to a target support assembly. The target support assembly may be the body support assembly 100 or the rotational support assembly 200. In the present disclosure, the flip assembly 302 connected to the body support assembly 100 may be a first flip assembly 302a, and the flip assembly 302 connected to the rotatable support assembly 200 may be a second flip assembly 302b. The first flip assembly 302a may include a first rotating arm 2a, a first end of the first flip assembly 302a may be fixedly connected to an end of the support base 301, and a second end of the first flip assembly 302a may be rotatably connected to the body support assembly 100. The second flip assembly 302b may include a second turning arm 2b, a first end of the second turning arm 2b may be fixedly connected to the other end of the support base 301, and a second end of the second turning arm 2b may be rotatably connected to the rotatable support assembly 200. In this case, the first rotating arm 2a and the second rotating arm 2b are provided at opposite ends of the support base 301, the first rotating arm 2a is rotatably connected to the body support assembly 100, and the second rotating arm 2b is rotatably connected to the rotatable support assembly 200. In this way, the relative rotation between the body support assembly and the hinge, and between the hinge and the rotatable support assembly can be easily realized by the rotation connection between the rotating arm and the target support assembly.

In the embodiment of the present disclosure, as shown in FIGS. 4 and 5, the rotating arm in the flip assembly 302 may be an arc-shaped slide plate, a side, facing towards the support base 301, of the target support assembly may be provided with a first arc-shaped chute matched with the arc-shaped slide plate, and at least a portion of the arc-shaped slide plate may be disposed in and rotatably connected to the first arc-shaped chute. In the present disclosure, the first rotating arm 2a may be a first arc-shaped slide plate a1, and the side, facing towards the support base 301, of the body support assembly 100 may be provided with a first arc-shaped chute A1 matched with the first arc-shaped slide plate a1; the second rotating arm 2b may be a second arc-shaped slide plate b1, and the side, facing towards the support base 301, of the rotatable support assembly 200 may be provided with a first arc-shaped chute A2 matched with the second arc-shaped slide plate b1. Taking the first arc-shaped slide plate a1 and the first arc-shaped chute A1 in the body support assembly 100 as examples, when the first arc-shaped slide plate a1 slides in the arc-shaped chute A1, the support base 301 can rotate in two different directions relative to the body support assembly 100, so as to change the angle between the hinge 300 and the body support assembly 100, and to realize the folding or unfolding of the display apparatus.

Optionally, the target support assembly may include: a support portion and a first connection block. A side, close to the support base 301, of the support portion may be provided with a mounting groove, and the first connection block may be secured in the mounting groove. A side, facing towards the rotating arm, of the first connection block may be provided with the first arc-shaped chute, and a surface, facing towards the flexible display panel, of the first connection block may be flush with a surface, facing towards the flexible display panel, of the support portion. The strength of the first connection block is greater than the strength of the support portion. In this case, by providing a mounting groove in the support portion in the target support assembly, the first connection block can be secured in the mounting groove, and it is ensured that the surface, facing towards the flexible display panel, of the first connection block is flush with the surface, facing towards the flexible display panel, of the support portion, which results in a better flatness of the flexible display panel. In addition, the strength of the first connection block is greater than the strength of the support portion, and the first arc-shaped chute is provided on the first connection block, which can ensure that the first arc-shaped chute basically does not deform during the process of the arc-shaped slide plate sliding in cooperation with the first arc-shaped chute, and ensures that the support base has better-sliding stability with the target support assembly. Exemplarily, the first connection block may be a structure made of a steel material, and the support portion may be a structure made of an aluminum material, such that the connection stability can be ensured, and a lower weight of the whole machine can be ensured.

In the present disclosure, as shown in FIGS. 4 and 5, the body support assembly 100 may include: a first support portion 101 and a first connection block B1. A side, close to the support base 301, of the first support portion 101 may be provided with a first mounting groove c1, and the first connection block B1 may be secured in the first mounting groove c1. A side, facing towards the first rotating arm 2a, of the first connection block B1 may be provided with a first arc-shaped chute A1, and a surface, facing towards the flexible display panel 400, of the first connection block B1 may be flush with a surface, facing towards the flexible display panel 400, of the first support portion 101. The rotatable support assembly 200 may include: a second support portion 201 and a first connection block B2. A side, close to the support base 301, of the second support portion 201 may be provided with a second mounting groove c2, and the first connection block B2 may be secured in the second mounting groove c2. A side, facing towards the second rotating arm 2b, of the first connection block B2 may be provided with a first arc-shaped chute A2, and a surface, facing towards the flexible display panel 400, of the first connection block B2 may be flush with a surface, facing towards the flexible display panel 400, of the second support portion 201.

In the embodiments of the present disclosure, a surface, facing towards the support base (i.e., a surface, facing towards the support base, of a side wall of the mounting groove), in an inner wall of the mounting groove in the support portion may be provided with a first positioning member and a surface, facing towards the flexible display panel, in the inner wall of the mounting groove (i.e., a bottom wall of the mounting groove) may be provided with a through hole. The first connection block may be provided with a second positioning member clamped with the first positioning member and a connection hole in communication with the through hole, the connection hole may be closer to the flexible display panel than the through hole to the flexible display panel. The target support assembly may further include: a fastener, an end of the fastener may be fastened to the connection hole on the first connection block upon passing through the through hole. In this case, the coordination of the first positioning member and the second positioning member can effectively ensure the installation accuracy of the first connection block in the mounting groove. Moreover, since the arrangement direction of the first positioning member and the second positioning member is perpendicular to the arrangement direction of the through hole and the connection hole, the first connection block can be effectively prevented from generating an undesirable phenomenon of local warping while connection the support portion and the first connection block through fewer fasteners. For example, the number of the fasteners may be one, and the number of through holes on the support portion and the number of connection holes on the first connection block may be one, which in turn can play a better role in sealing the interior of the display apparatus. Exemplarily, one of the first positioning member and the second positioning member may be a positioning column and the other may be a positioning hole, and the embodiments of the present disclosure are schematically illustrated with the first positioning member being a positioning hole and the second positioning member being a positioning column.

In the present disclosure, as shown in FIGS. 4 and 5, a surface, facing towards the support base 301, in an inner wall of the first mounting groove c1 in the first support portion 101 may be provided with a first positioning member 101a, and a surface, facing towards the flexible display panel 400, in the inner wall of the first mounting groove c1 may be provided with a first through hole 101b. The first connection block B1 may be provided with a second positioning member B11 clamped with the first positioning member 101a and a first connection hole (not shown in the figures) in communication with the first through hole 101b. The first connection block B1 may be provided with a second positioning member B11 be provided with the first positioning member 101a and a first connection hole (not shown in the figures) in communication with the first through hole 101b. The first connection hole may be closer to the flexible display panel 400 than the first through hole 101b to the flexible display panel 400. The body support assembly 100 may further include: a first fastener (not shown in the figures), an end of the first fastener may be fastened to the first connection hole on the first connection block B1 upon passing through the first through hole 101b. In this way, the positioning of the first connection block B1 and the first mounting groove c1 is realized through the cooperation of the first positioning member 101a and the second positioning member B11, and the fixed connection of the first connection block B1 and the first support portion 101 is realized through the first fastener connection to the first connection hole upon passing through the first through hole 101b. A surface, facing towards the support base 301, in an inner wall of the second mounting groove c2 in the second support portion 201 may be provided with a first positioning member (not shown in the figures), and a surface, facing towards the flexible display panel 400, in the inner wall of the second mounting groove c2 may be provided with a second through hole 201b. The first connection block B2 may be provided with a second positioning member B21 clamped with the first positioning member and a second connection hole (not shown in the figures) in communication with the second through hole 201b. The second connection hole (not shown in the figures) may be closer to the flexible display panel 400 than the second through hole 201b to the flexible display panel 400. The rotatable support assembly 200 may also include: a second fastener (not shown in the figures), an end of the second fastener may be fastened to the second connection hole in the first connection block B2 upon passing through the second through hole 201b. In this way, the positioning of the first connection block B2 and the second mounting groove c2 is realized through the cooperation of the first positioning member and the second positioning member B21, and the fixed connection of the first connection block B2 and the second support portion 201 is realized through the second fastener connected to the second connection hole upon passing through the second through hole 201b.

Optionally, a chute opening allowing the arc-shaped slide plate to slide into and a limit blind end opposite to the chute opening are arranged in the first arc-shaped chute, and a first limit protrusion is arranged on an inner wall of the first arc-shaped chute. A second limit protrusion matched with the first limit protrusion is arranged at an end portion of the arc-shaped slide plate. In the case that the display apparatus is in the folded state, the end portion of the arc-shaped slide plate may be abutted against a limit blind end of the first arc-shaped chute; and in the case that the display apparatus is in the unfolded state, the first limit protrusion is abutted against the second limit protrusion. In the present disclosure, as shown in FIGS. 4 and 5, the first arc-shaped slide plate a1 and the first arc-shaped chute A1 are taken as examples for schematic illustration: a chute allowing the first arc-shaped slide plate a1 to slide into and a first limit blind end d1 disposed opposite to the chute opening are arranged in the first arc-shaped chute A1 on the body support assembly 100 and, and a first limit protrusion d2 is arranged on an inner wall of the first arc-shaped chute A1. A second limit protrusion d3 matched with the first limit protrusion d2 is arranged at an end portion of the first arc-shaped slide plate a1. In this way, during the switching of the display apparatus from the unfolded state to the folded state, the first arc-shaped slide plate a1 can slide in the first arc-shaped chute A1 in a direction close to the first limit blind end d1 of the first limit protrusion, and after being rotated to a target angle, an end portion of the first arc-shaped slide plate a1 can be abutted against the first limit blind end d1 of the first arc-shaped chute A1. In this way, excessive rotation of the support base 301 can be avoided, and a side of the first limit blind end d1, facing towards the flexible display panel 400, of the first arc-shaped chute A1 can effectively support the flexible display panel 400. In the process of switching the display apparatus from the folded state to the unfolded state, the first arc-shaped slide plate a1 drives the second limit protrusion d3 to move in a direction close to the first limit protrusion d2 in the first arc-shaped chute A1; and in the case that the display apparatus is in the unfolded state, a surface of the second limit protrusion d3 may be abutted against a surface of the first limit protrusion d2 to realize the limit in the unfolded state. It should be noted that the limit principle of the second arc-shaped slide plate b1 and the first arc-shaped chute A2 by the first limit protrusion and the second limit protrusion can be referred to the limit principle of the first arc-shaped slide plate a1 and the first arc-shaped chute A1 as described above, and will not be repeated herein.

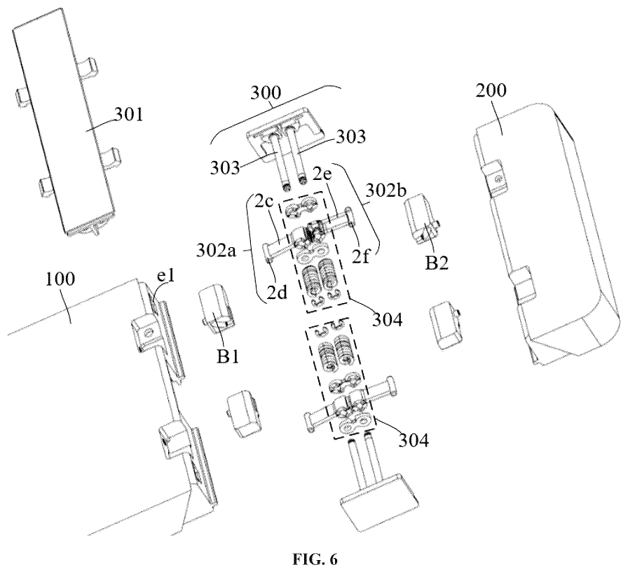

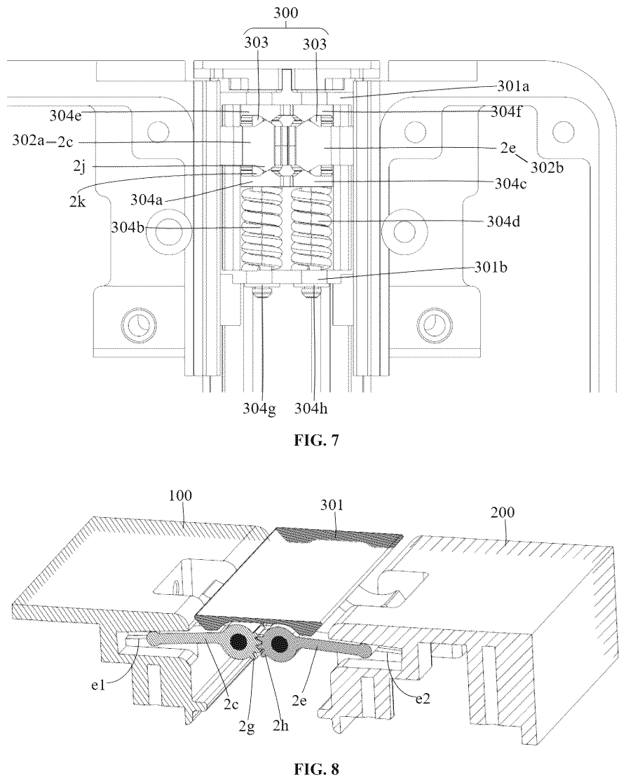

In the embodiments of the present disclosure, referring to FIG. 6, FIG. 7, and FIG. 8, FIG. 6 is a partial structural exploded schematic diagram of a display apparatus according to some embodiments of the present disclosure, FIG. 7 is a partial schematic structural diagram of another display apparatus according to some embodiments of the present disclosure, and FIG. 8 is a cross-sectional view of another display apparatus according to some embodiments of the present disclosure. The flip assembly 302 may further include: a drive rod and a first protrusion portion, one end of the drive rod may be rotatably connected to the support base 301, and another end of the drive rod may be fixedly connected to the first protrusion portion. A side, facing towards the support base 301, of the target support assembly may be provided with a linear chute, another end of the drive rod may extend into the linear chute, and the first protrusion portion may be capable of sliding within the linear chute relative to the target support assembly. In this case, in the process of the support base realizing rotation with the target support assembly through the rotating arm, the end of the drive rod can rotate relative to the support base, and the first protrusion portion fixed to another end of the drive rod can slide within the linear chute in the target support assembly. It should be noted that the axis of rotation of the drive rod relative to the support base is parallel to, but does not coincide with, the axis of rotation of the arc-shaped slide plate relative to the first arc-shaped chute.

In the present disclosure, as shown in FIGS. 6, 7, and 8, the first flip assembly 302a may include: a first drive rod 2c and a first protrusion portion 2d, one end of the first drive rod 2c may be rotatably connected to the support base 301, and another end of the first drive rod 2c may be fixedly connected to the first protrusion portion 2d. A side, facing towards the support base 301, of the body support assembly 100 may be provided with a first linear chute e1, another end of the first drive rod 2c may extend into the first linear chute e1, and the first protrusion portion 2d may be capable of sliding within the first linear chute e1 relative to the body support assembly 100. The second flip assembly 302b may include: a second drive rod 2e and a first protrusion portion 2f, an end of the second drive rod 2e may be rotatably connected to the support base 301, and another end of the second drive rod 2e may be fixedly connected to the first protrusion portion 2f. A side, facing towards the support base 301, of the rotatable support assembly 200 may be provided with a second linear chute e2, an other end of the second drive rod 2e may extend into the second linear chute e2, and the first protrusion portion 2f may be capable of sliding within the second linear chute e2 relative to the rotatable support assembly 200.

Optionally, as shown in FIGS. 6, 7, and 8, the hinge 300 may further include: two connection shafts 303 corresponding to two flip assemblies 302 opposite to each other, the two connection shafts may be secured in the support base 301, and an end of the drive rod in each flip assembly may be sleeved on and rotatably connected to a corresponding connection shaft. In this case, by fixing two side-by-side distributed connection shafts 303 at the side, facing away from the flexible display panel 400, of the support base 301, an end of the drive rod can be sleeved on the connection shaft and rotatably connected to the connection shaft, thereby realizing the rotating connection between the drive rod and the support base. Exemplarily, an end of the first drive rod 2c may be sleeved on one of the connection shafts 303 and rotatably connected to this connection shaft; an end of the second drive rod 2e may be sleeved on the other connection shaft 303 and rotatably connected to the connection shaft.

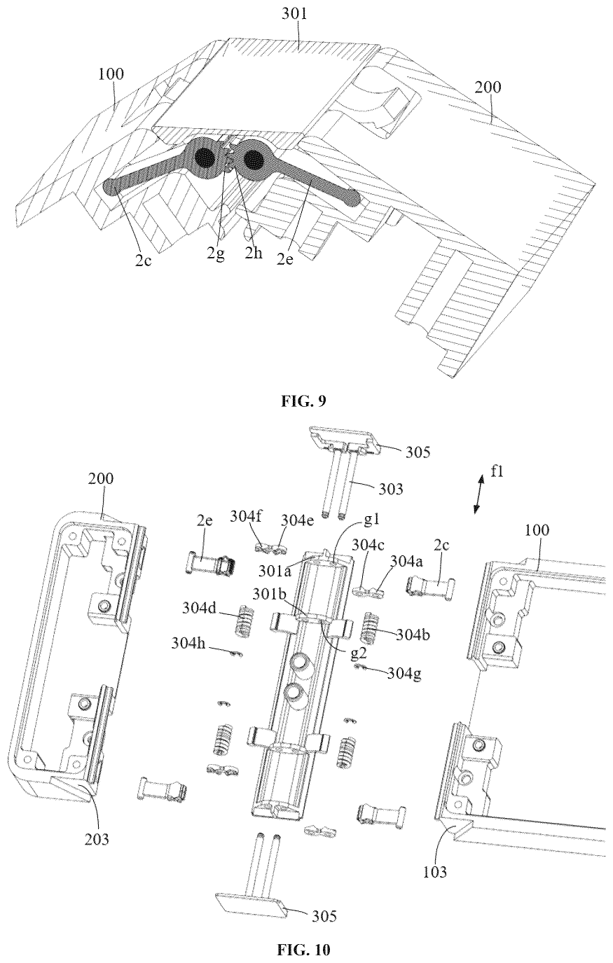

In the embodiments of the present disclosure, an end, facing away from the first protrusion portion, of the drive rod in the flip assembly may be provided with a plurality of synchronizing external teeth. Two drive rods in two flip assemblies opposite to each other are meshed via the synchronizing external teeth. In the present disclosure, as shown in FIG. 6, FIG. 7, FIG. 8, and FIG. 9, FIG. 9 is a schematic effect diagram of a display apparatus in a folded state according to some embodiments of the present disclosure. An end, facing away from the first protrusion portion 2d, of the first drive rod 2c may be provided with a plurality of first synchronizing external teeth 2g, and an end, facing away from the first protrusion portion 2f, of the second drive rod 2e may be provided with a plurality of second synchronizing external teeth 2h, with the plurality of first synchronizing external teeth 2g and the plurality of second synchronizing external teeth 2h meshing. In this way, during the rotation of the support base 301 relative to the body support assembly 100, an end of the first drive rod 2c rotates around the connection shaft 303, and at the same time, through the meshing of the first synchronizing external teeth 2g and the second synchronizing external teeth 2h, the second drive rod 2e can be driven to rotate around the connection shaft 303, which will in turn drive the rotatable support assembly 200 to rotate relative to the support base 301, i.e., synchronous rotation can be achieved, and the user experience is improved.

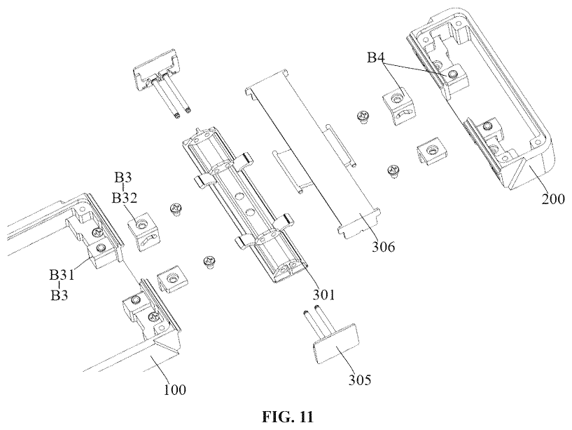

Optionally, as shown in FIGS. 6, 7, and 8, the hinge 300 may further include: a torsion mechanism 304 connected to the two connection shafts 303. The torsion mechanism 304 may be configured to: provide a damping force in the case that the target support assembly is rotated relative to the support base. In this case, by providing the torsion mechanism 304 in the hinge 300, the damping force can be provided when the target support assembly is rotated relative to the support base, i.e., the damping effect when the display apparatus is switched between the folded state and the unfolded state is increased. In the present disclosure, the torsion mechanism 304 may include: a torsion member and an elastic element sleeved on each of the connection shafts 303, the torsion member may be abutted against a portion, sleeved on the connection shaft, of the drive rod, and the elastic element may be disposed on a side, facing away from the drive rod, of the torsion member. The two torsion members sleeved on the two connection shafts are fixedly connected. In this case, the use of the elastic element can apply a force to the torsion member, such that the torsion member can simultaneously apply a squeezing force to the drive rods sleeved on the two connection shafts, which in turn can provide a damping force for the body support assembly to rotate relative to the support base, as well as for the rotatable support assembly to rotate relative to the support base, and realize the hovering function at different angles. Exemplarily, referring to FIG. 7 and FIG. 10, FIG. 10 is a partial exploded schematic structural diagram of another display apparatus according to some embodiments of the present disclosure. The torsion mechanism 304 may include: a first torsion member 304a and a first elastic element 304b sleeved on one connection shaft 303, the first torsion member 304a may be abutted against a portion, sleeved on this connection shaft, of the first drive rod 2c, and the first elastic element 304b is disposed on a side of the first torsion member 304a facing away from the first drive rod 2c; the torsion mechanism 304 also includes: a second torsion member 304c and a second elastic element 304d sleeved on the other connection shaft, the second torsion member 304c may be abutted against a portion, sleeved on the connection shaft 303, of the first drive rod 2e, and the second elastic element 304d is disposed on a side, facing away from the first drive rod 2e of the second torsion member 304c. It should be noted that the first elastic element 304b and the second elastic element 304d may be a coil spring or a plurality of disc springs provided in a cascade, which is not specifically limited in the embodiments of the present disclosure.

In the embodiments of the present disclosure, a portion, sleeved on the connection shaft, of the drive rod may be provided with a plurality of first abutment portions on a side facing towards the torsion member, and a side, facing towards the drive rod, of the torsion member is provided with a plurality of second abutment portions. Exemplarily, one of the first abutment portion and the second abutment portion may be a raised portion and the other may be a recessed portion. As shown, the portion, sleeved on the connection shaft, of the drive rod may be provided with a plurality of first raised portions on the side facing towards the torsion member, and the side, facing towards the drive rod, of the torsion member is provided with a plurality of first recessed portions. Exemplarily, taking the plurality of first raised portions 2j on the first drive rod 2c and the plurality of first recessed portions 2k on the first torsion member 304a as an example, when the display apparatus is in a fully unfolded state, the first raised portions 2j on the first drive rod 2c may be disposed within the first recessed portions 2k on the first torsion member 304a to enable the display apparatus to be maintained at a particular angle, and when the user touches or presses the flexible screen, the display apparatus will not be easily folded under external force. When the display apparatus is in a fully folded state, the first raised portion 2j on the first drive lever 2c may be disposed within the first recessed portion 2k on the first torsion member 304a to enable the display apparatus to maintain at a particular angle. When the user is touching or pressing the flexible screen, the display apparatus will not be unfolded arbitrarily under the action of an external force, such that the safety of the display apparatus can be ensured. It should be noted that hovering of the display apparatus at any position between fully unfolded and fully folded can also be realized by the cooperation of the plurality of first raised portions and the plurality of first recessed portions.

Optionally, the torsion mechanism 304 in the hinge 300 may further include: an auxiliary torsion member sleeved on each of the connection shafts 303. The auxiliary torsion member may be disposed on a side, facing away from the torsion member, of the drive rod, and the auxiliary torsion member may be abutted against the portion, sleeved on the connection shaft, of the drive rod. Two auxiliary torsion members sleeved on the two connection shafts are fixedly connected. In this case, by providing the auxiliary torsion members in the torsion mechanism, the degree of compression of the elastic element can be ensured by the cooperation between the auxiliary torsion member and the torsion member to obtain sufficiently large damping. In the present disclosure, as shown in FIGS. 7 and 10, the torsion mechanism 304 includes: a first auxiliary torsion member 304e sleeved on one connection shaft 303, and a second auxiliary torsion member 304f sleeved on the other connection shaft 303. The first auxiliary torsion member 304e and the second auxiliary torsion member 304f are fixedly connected. It should be noted that the structure of the auxiliary torsion member and the structure of the torsion member may be the same, and the principle of the auxiliary torsion member and the drive rod abutting to generate a torsion may be the same as the principle of the torsion member and the drive rod abutting to generate a torsion force, which will not be repeated here.

In the embodiments of the present disclosure, as shown in FIGS. 7 and 10, the support base 301 in the hinge 300 may be provided with a first limit plate 301a and a second limit plate 301b opposite to each other, and the first limit plate 301a and the second limit plate 301b may be arranged in a direction parallel to the extension direction of the support base 301, and two end portions of the connection shaft 303 may be connected to the first limit plate 301a and the second limit plate 301b, respectively. The auxiliary torsion member, the drive rod, the torsion member, and the elastic element in the torsion mechanism 304 are sequentially disposed between the first limit plate 301a and the second limit plate 301b, and an end, facing away from the torsion member, of the elastic element may be abutted against the second limit plate. Exemplarily, the first limit plate 301a may be disposed on an end portion of the support base 301, and the second limit plate 301b may be disposed at a certain distance from the first limit plate 301a. The distance may be set according to the sizes of the auxiliary torsion member, the drive rod, the torsion member, and the elastic element in the torsion mechanism. In the present disclosure, as shown in FIG. 10, the first limit plate 301a may be provided with two first via holes g1, and the second limit plate 301b may be provided with two second via holes g2 in corresponding communication with the two first via holes g1. The torsion mechanism 304 may further include: a first locking member 304g and a second locking member 304h, and an end of a connection shaft 303 may be disposed on a side, facing away from the first limit plate 301a, of the second limit plate 301b after sequentially passing through one via hole g1 and one via hole g2, and the first locking member 304g may be clamped with an end of the connection shaft 303 and be abutted against the second limit plate 301b. Another end of the connection shaft 303 may be disposed on a side, facing away from the second limit plate 301b, of the first limit plate 301a and may be fastened to the second limit plate 301b, such that this connection shaft 303 cannot be separated from the support base 301 and cannot rotate relative to the support base 301. An end of the other connection shaft 303 may be disposed on a side, facing away from the first limit plate 301a, of the second limit plate 301b upon sequentially passing through the other first via hole g1 and the other second via hole g2, and the second locking member 304h may be clamped with an end of the other connection shaft 303 and be abutted against the second limit plate 301b. The other end of the other connection shaft 303 may be disposed on a side, facing away from the second limit plate 301b, of the first limit plate 301a and may be fastened to the second limit plate 301b, such that this connection shaft 303 cannot be separated from the support base and cannot rotate relative to the support base 301.

In the present disclosure, as shown in FIG. 10, the hinge 300 may further include: two protective side plates 305 connected to two ends of the support base 301, and the support base 301 may be disposed between the two protective side plates 305 in the second direction f1. A side of the target support assembly may be provided with an avoidance groove matched with the protective side plates 305. Exemplarily, a side of the target support assembly 100 may be provided with a first avoidance groove 103 matched with protective side plates 305, and a side of the rotatable support assembly 200 may be provided with a second avoidance groove 203 matched with the protective side plates 305. In this case, by providing the protective side plates 305 at each end of the support base 301, the two sides of the support base 301 can be protected by the protective side plates 305, and in the process of bending the display apparatus, the first avoidance groove 103 in the body support assembly 100 can avoid the protective side plates 305 without interfering with the normal rotation of the body support assembly 100, and at the same time, the second avoidance groove 203 in the rotatable support assembly 200 can avoid the protective side plates 305 without interfering with the normal rotation of the rotatable support assembly 200. In other possible implementations, the other ends of the two connection shafts 303 may be fixedly connected to the protective side plates 305 on a side where the first limit plate 301a is facing away from the second limit plate 301b.

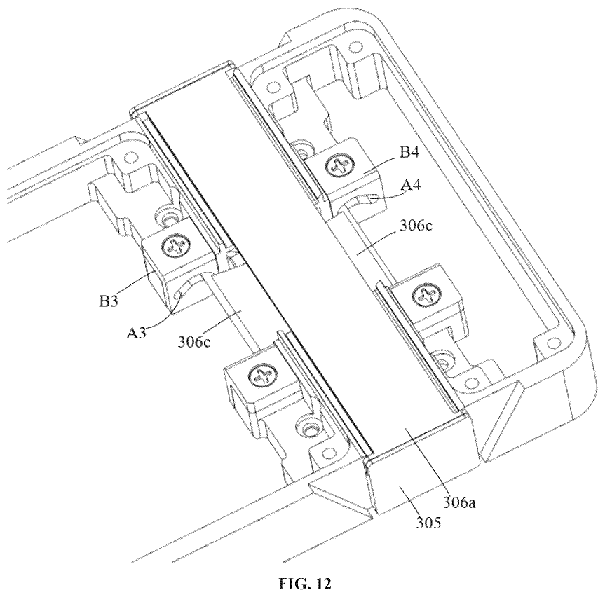

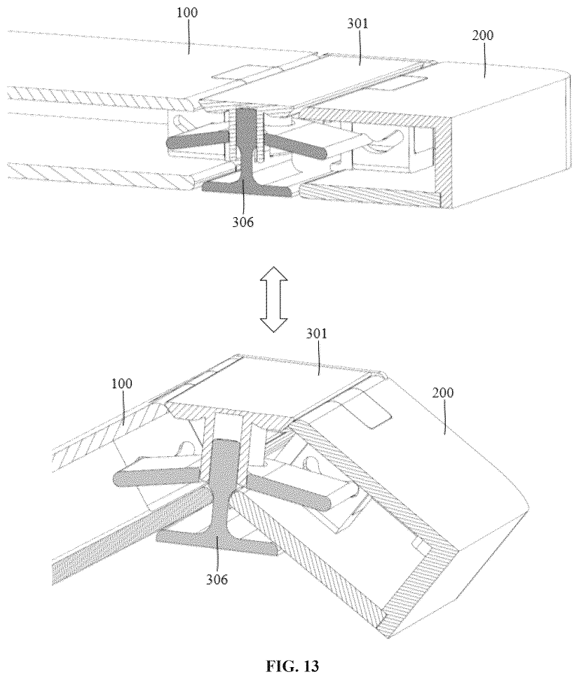

Optionally, referring to FIG. 11 and FIG. 12, FIG. 11 is a partial exploded schematic diagram of a portion of the structure of yet another display apparatus according to some embodiments of the present disclosure, and FIG. 12 is a partial schematic structural diagram of yet another display apparatus according to some embodiments of the present disclosure. The hinge 300 may further include: a protective member 306 movably connected to a side, facing away from the flexible display panel 400, of the support base 301, and the protective member 306 may be used to cover at least a portion of the flip assembly and at least a portion of the torsion mechanism 304. The protective member 306 may be slidably connected to the body support assembly 100 and the rotatable support assembly 200, respectively. The protective member 306 may be configured to move along a direction away from the support base 301 during switching of the display apparatus from the unfolded state to the folded state, and to move along a direction close to the support base 301 during switching of the display apparatus from the folded state to the unfolded state. In this case, by providing a protective member on the rear surface of the display apparatus, the protective member can protect the parts between the protective member and the support base by the protective member, and can provide a certain modification to the rear surface of the display apparatus. Furthermore, referring to FIG. 13, FIG. 13 is a schematic effect diagram of switching between an unfolded state and a folded state of a display apparatus according to some embodiments of the present disclosure. To prevent the body support assembly 100 and the rotatable support assembly 200 from interfering with the movement of the protective member 306 during the bending of the display apparatus, the protective member 306 is slidably connected to the body support assembly 100 and the rotatable support assembly 200, respectively, such that when the body support assembly 100 and the rotatable support assembly 200 rotate relative to the support base 301, the protective member 306 can be driven to move along a direction away from the support base 301, ensuring normal bending of the display apparatus.

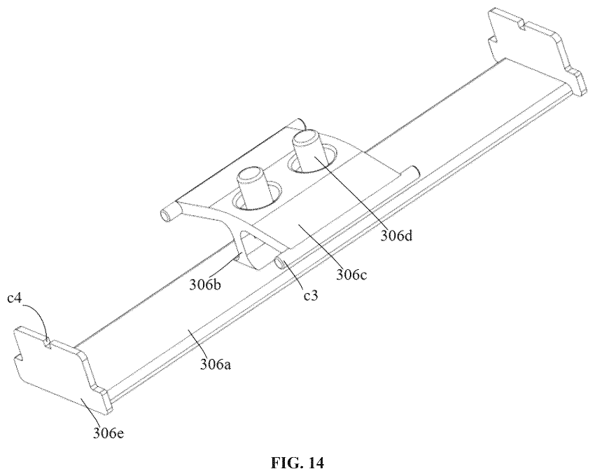

In the embodiments of the present disclosure, referring to FIG. 14, FIG. 14 is a schematic structural diagram of a protective member according to some embodiments of the present disclosure. The target support assembly may include: a support portion and a second connection block. The second connection block may be fixedly connected to a side, facing away from the flexible display panel, of the support portion, and a side of the second connection block is provided with a second arc-shaped chute. The protective member 306 may include: a protective plate 306a, an extension portion 306b fixed to a side, facing towards the support base 301, of the protective plate 306a, and a rotating plate 306c fixedly connected to a side, facing away from the protective plate 306a, of the extension portion 306b. The rotating plate 306c may be provided with a second protrusion portion c3 matched with the second arc-shaped chute on the second connection block, and the second protrusion portion c3 can be slidably connected to the second connection block within the second arc-shaped chute. In this case, by the cooperation of the second protrusion portion c3 on the rotating plate 306c and the second arc-shaped chute on the second connection block, in the process of bending the display apparatus, the target support assembly, through the limit effect of the second arc-shaped chute on the second protrusion portion, causes the second protrusion portion c3 to slide from one end of the second arc-shaped chute to the other end of the second arc-shaped chute, and thus drives the protective member 306 to move. It should be noted that the arc length of the second arc-shaped chute may be set according to the actual moving distance of the protective member.

In the present disclosure, as shown in FIGS. 11 and 12, the body support assembly 100 may include: a first support section 101 and a second connection block B3. The second connection block B3 may be fixedly connected to a side, facing away from the flexible display panel 400, of the first support section 101, and a side of the second connection block B3 may be provided with a second arc-shaped chute A3. The rotatable support assembly 200 may include: a second support section 201 and a second connection block B4. The second connection block B4 may be fixedly connected to a side, facing away from the flexible display panel 400, of the second support portion 201, and a side of the second connection block B4 may be provided with a second arc-shaped chute A4. The number of rotating plates in the protective member 305 may be two, and each rotating plate is provided with a second protrusion portion. Exemplarily, taking the second connection block B3 as an example, the second connection block B3 may include: a second connection block body B31, and a connection plate B32 fixedly connected to the second connection block body B31. A side of the connection plate B32 may be provided with a second arc-shaped chute A3, and the strength of the connection plate B32 may be greater than the strength of the second connection block body B31. In this case, by setting the second arc-shaped chute A3 on the connection plate B32, the strength of the connection plate B32 is greater, such that the second protrusion portion c3 has better stability when sliding within the second arc-shaped chute A3. Moreover, the connection plate B32 is fixed to the second connection block body B31 after the second arc-shaped chute A3 is processed on the connection plate B32, simplifying the preparation process of the second arc-shaped chute. It should be noted that the structure of the second connection block B4 is the same as the structure of the second connection block B3, and will not be repeated here.

In the present disclosure, as shown in FIG. 12, the target support assembly may include: two second connection blocks, the rotating plate may be disposed between the two second connection blocks, and the rotating plate may be provided with two second protrusion portions disposed opposite to each other. The two second protrusion portions may be respectively disposed in the two second arc-shaped chutes of the two second connection blocks. That is, both the body support assembly and the rotatable support assembly may include two second connection blocks disposed opposite to each other. In this case, by providing two second connection blocks in the target support assembly, the rotating plate in the protective member can be disposed between the two second connection blocks, and the two second protrusion portions on the two rotating plates can be cooperatively connected to the two second arc-shaped chutes of the two second connection blocks, respectively, such that the connection stability of the protective member and the rotatable support assembly, as well as the body support assembly, is effectively increased.

Optionally, referring to FIG. 15, FIG. 15 is a schematic structural diagram of a support base according to some embodiments of the present disclosure. The protective member 306 may further include: a first guide member 306d fixedly connected to a side, facing away from the protective plate 306a, of the extension portion 306b, and a side, facing towards the protective plate 306a, of the support base 301 may be provided with a second guide member 301c. One of the first guide member 306d and the second guide member 301c may be a blind hole, and another of the first guide member 306d and the second guide member 301c may extend into the blind hole and be capable of sliding within the blind hole. In the present disclosure, the protective member 306 may further include: a first guide plate 306e fixedly connected to an end of the protective plate 306a. The first guide plate 306e is vertically disposed to the protective plate 306a, and a side, facing towards the support base 301, of the first guide plate 306e is provided with a guide groove c4. The support base 301 may also be provided with a second guide plate 301d, the second guide plate 301d may be disposed on a side, facing away from the support base 301, of the first limit plate 301a, and a portion of the second guide plate 301d may be disposed within the guide groove c4 and slidably connected to the first guide plate 306e.

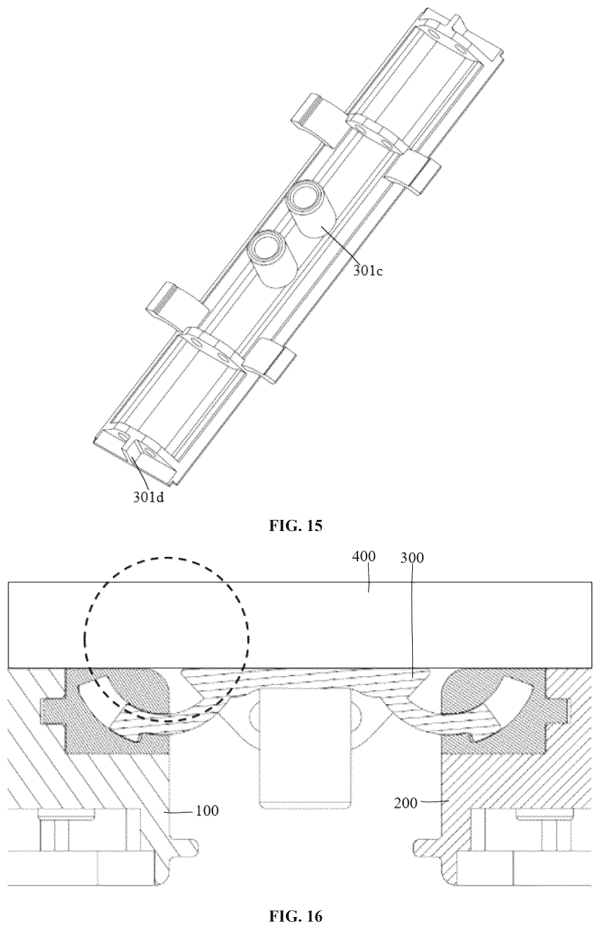

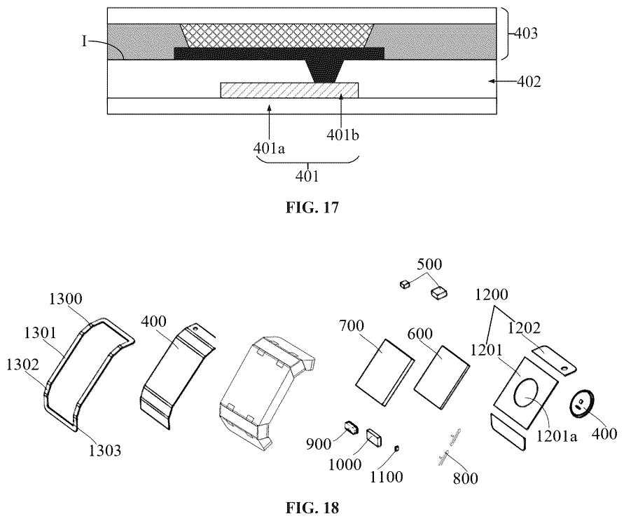

In the embodiments of the present disclosure, referring to FIG. 16 and FIG. 17, FIG. 16 is a side schematic diagram of a display apparatus when a flexible display panel is unfolded according to some embodiments of the present disclosure, and FIG. 17 is a schematic diagram of a membrane layer structure of a flexible display panel according to some embodiments of the present disclosure. The flexible display panel 400 in the display apparatus may include: a driving backplane 401, a planarization layer 402 disposed on a side of the driving backplane 401, and a plurality of light-emitting devices 403 disposed on a side, facing away from the driving backplane 401, of the planarization layer 402. The plurality of light-emitting devices 403 may be electrically connected to the driving backplane 401. An axis of rotation of the support base 301 in the hinge 300 when rotating relative to the body support assembly 100 (the axis of rotation passes through a virtual center of a circle of the first arc-shaped chute A1) may be disposed in a surface I, facing away from the driving backplane 401, of the planarization layer 402; an axis of rotation of the rotatable support assembly 200 when rotating relative to the support base 301 in the hinge 300 (the axis of rotation passes through a virtual center of a circle of the first arc-shaped chute A2), may be disposed in the surface I, facing away from the driving backplane 401, of the planarization layer 402. In this case, the axis of rotation of the support base 301 in the hinge 300 when rotating relative to the body support assembly 100 is disposed in the surface, facing away from the driving backplane 401, of the planarization layer 402, and the axis of rotation of the rotatable support assembly 200 when rotating relative to the support base 301 in the hinge 300 is disposed in the surface, facing away from the driving backplane 401, of the planarization layer 402. In this way, in the process of switching between the unfolded state and the folded state of the display apparatus, the dislocation caused by the inner and outer diameters of the flexible display panel 400 during rotation of the rotatable support assembly and the hinge can be effectively avoided, thereby avoiding tensile/compressive stresses on the flexible display panel 400, and ensuring that the display effect of the flexible display panel 400 is better. In the present disclosure, the driving backplane 401 may include: a flexible substrate 401a, and a plurality of driving circuits 401b disposed on a side, close to the planarization layer 402, of the flexible substrate 401a, and the driving circuits 401b are used to drive the light-emitting devices 403.

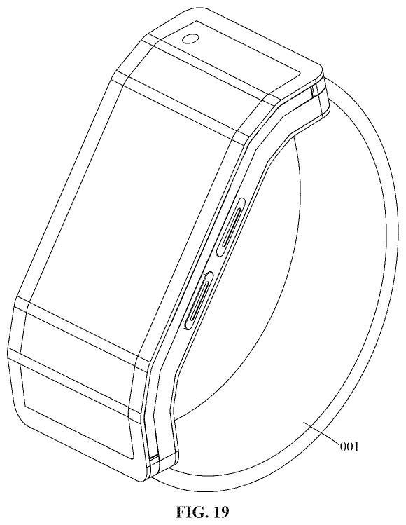

Optionally, in the display apparatus in the present disclosure, the structure composed of the body support assembly, the rotatable support assembly, and the hinge may serve as a middle frame of the display apparatus. The rear surface of the body support assembly and the rear surface of the rotatable support assembly may be provided with a cavity (not shown in the figures), referring to FIG. 18, FIG. 18 is an exploded schematic diagram of a display apparatus according to some embodiments of the present disclosure. The display apparatus may also include a plurality of functional modules, which may include: a camera 500, a battery 600, a motherboard 700, a key module 800, a card tray for assembling a SIM, a speaker 900, a motor 1000, and a microphone 1100, and the like.

As shown in FIG. 18, the display apparatus may further include: a base plate 1200 and a cladding member 1300, the base plate 1200 may be fixedly connected to a side, facing away from the flexible display panel 400, of the middle frame, the cladding member 1300 may be disposed on a side, facing away from the middle frame, of the flexible display panel 400, and the cladding member 1300 may cover a non-display region of the flexible display panel 400. The cladding member 1300 may include: a first rigid frame 1301 corresponding to the body support assembly 100, a first flexible frame 1302 corresponding to the hinge 300, and a second rigid frame 1303 corresponding to the rotatable support assembly 200. The cladding member 1300 may be clamped and connected to the middle frame.

Exemplarily, the base plate 1200 may include: a first base plate 1201 and a second base plate 1202. The first base plate 1201 may be fixedly connected to a side, facing away from the flexible display panel 400, of the body support assembly 100, and the second base plate 1202 may be fixedly connected to a side, facing away from the flexible display panel 400, of the rotatable support assembly 200. In the present disclosure, a side, facing away from the flexible display panel 400, of the first base plate 1201 may be provided with an aperture 1201a, and the display apparatus may further include: a sign detection module 1400 disposed in the middle frame. At least a portion of the sign detection module 1400 may be exposed from the aperture 1201a of the first base plate 1201. In this case, when the display apparatus is integrated into a wearable device, characteristics such as heart rate, body fat rate, and the like of the human body can be detected by the sign detection module 1400.

In summary, the embodiments of the present disclosure provide a display apparatus that may include: a body support assembly, two rotatable support assemblies, a hinge, and a flexible display panel. By providing the hinge between the body support assembly and the rotatable support assembly in the display apparatus, at least two flip assemblies in the hinge are disposed on two sides of the support base and are connected to the support base, wherein one flip assembly is rotatably connected to the body support assembly, and another flip assembly is rotatably connected to the rotatable support assembly. When the display apparatus is switched between the unfolded state and the folded state, the hinge can rotate at a certain angle relative to the body support assembly under the action of an external force, and the rotatable support assembly can also rotate at a certain angle relative to the hinge. In this case, the flexible display panel can also be folded into different patterns under the drive of the hinge and the rotatable support assembly, such that the display apparatus provided with the flexible display panel in the present disclosure supports various different folding patterns, which improves the flexibility in use of the display apparatus, and improves user experience.

Embodiments of the present disclosure also provide a wearable device, referring to FIG. 19, FIG. 19 is a schematic structural diagram of a wearable device according to some embodiments of the present disclosure. The wearable device may include: a display apparatus, and a watchband 001 detachably connected to the display apparatus. The display apparatus may be the display apparatus as given in any of the above embodiments. Exemplarily, when the display apparatus is a device body in the wearable device, the wearable device may be a watch, a bracelet, or the like. For example, when the display apparatus is a smartphone, the display apparatus can be worn on the user's wrist as a watch after being bent and connected to a watchband. When the display apparatus is unfolded, the watchband can be removed from the display apparatus, which can be used as a cell phone.

It should be noted that, in the accompanying drawings, the dimensions of the layers and regions may be exaggerated for clarity of illustration. Moreover, it should be understood that, in the case that an element or layer is referred to as being “on” another element or layer, it may be directly on the other element, or an intermediate layer may be present. In addition, it should be understood that, in the case that an element or layer is referred to as being “under” another element or layer, it may be directly under the other element, or one or more intermediate layers or elements may be present. In addition, it can also be understood that, in a case that a layer or element is referred to as being “between” two layers or elements, it may be the only layer between the two layers or elements, or one or more intermediate layers or elements may also be present. Like reference numerals refer to like elements throughout the present disclosure.

In the present disclosure, the terms “first” and “second” are merely used for descriptive purposes and should not be construed as indicating or implying the relative importance. The term “a plurality of” refers to two or more, unless otherwise explicitly defined.

Described above are merely optional embodiments of the present disclosure, and are not intended to limit the present disclosure. Within the spirit and principles of the present disclosure, any modifications, equivalent substitutions, improvements, and the like should fall within the scope of protection of the present disclosure.

1. A display apparatus, comprising:
a body support assembly;
two rotatable support assemblies disposed on two sides of the body support assembly in a first direction;
a hinge disposed between the body support assembly and the rotatable support assembly in the first direction, wherein the hinge comprises a support base and at least two flip assemblies, wherein the support base extends along a second direction intersected with the first direction; and the at least two flip assemblies are oppositely disposed in the first direction and are both connected to the support base, one of the at least two flip assemblies is connected to the body support assembly, and another of the at least two flip assemblies is connected to the rotatable support assembly; and
a flexible display panel, wherein a rear surface of the flexible display panel is connected to the body support assembly, the support base, and the rotatable support assemblies.

2. The display apparatus according to claim 1, wherein each of the at least two flip assemblies comprises a rotating arm, wherein a first end of the rotating arm is fixedly connected to the support base, and a second end of the rotating arm is rotatably connected to a target support assembly, the target support assembly being the body support assembly or the rotatable support assembly.

3. The display apparatus according to claim 2, wherein the rotating arm is an arc-shaped slide plate, and a first arc-shaped chute matched with the arc-shaped slide plate is arranged in a side, facing towards the support base, of the target support assembly, at least a portion of the arc-shaped slide plate being disposed in and rotatably connected to the first arc-shaped chute.

4. The display apparatus according to claim 3, wherein the target support assembly comprises a support portion and a first connection block; wherein
a mounting groove is arranged in a side, close to the support base, of the support portion; and
the first connection block is secured in the mounting groove, the first arc-shaped chute is arranged in a side, facing towards the rotating arm, of the first connection block, and a surface, facing towards the flexible display panel, of the first connection block is flush with a surface, facing towards the flexible display panel, of the support portion;
wherein a strength of the first connection block is greater than a strength of the support portion.

5. The display apparatus according to claim 4, wherein a first positioning member is arranged on a surface, facing towards the support base, in an inner wall of the mounting groove, and a through hole is arranged in a surface, facing towards the flexible display panel, in the inner wall of the mounting groove;
a second positioning member clamped with the first positioning member and a connection hole in communication with the through hole are arranged on the first connection block, the connection hole being closer to the flexible display panel than the through hole to the flexible display panel; and
the target support assembly further comprises a fastener, an end of the fastener being fastened to the connection hole upon passing through the through hole.

6. The display apparatus according to claim 3, wherein a chute opening allowing the arc-shaped slide plate to slide into and a limit blind end opposite to the chute opening are arranged in the first arc-shaped chute, and a first limit protrusion is arranged on an inner wall of the first arc-shaped chute; and
a second limit protrusion matched with the first limit protrusion is arranged at an end portion of the arc-shaped slide plate;
wherein in a case that the display apparatus is in a folded state, the end portion of the arc-shaped slide plate is abutted against the limit blind end of the first arc-shaped chute; and
in a case that the display apparatus is in an unfolded state, the first limit protrusion is abutted against the second limit protrusion.

7. The display apparatus according to claim 2, wherein each of the at least two flip assemblies further comprises a drive rod and a first protrusion portion, wherein one end of the drive rod is rotatably connected to the support base, and another end of the drive rod is fixedly connected to the first protrusion portion; and
a linear chute is arranged in a side, facing towards the support base, of the target support assembly, the another end of the drive rod extends into the linear chute, and the first protrusion portion is capable of sliding within the linear chute relative to the target support assembly.

8. The display apparatus according to claim 7, wherein the hinge further comprises two connection shafts corresponding to two flip assemblies opposite to each other, wherein the two connection shafts are secured in the support base, and an end of the drive rod in the flip assembly is sleeved on and rotatably connected to a corresponding connection shaft.

9. The display apparatus according to claim 8, wherein a plurality of synchronizing external teeth are arranged at an end, facing away from the first protrusion portion, of the drive rod;
wherein two drive rods in the two flip assemblies opposite to each other are meshed via the synchronizing external teeth.

10. The display apparatus according to claim 8, wherein the hinge further comprises a torsion mechanism connected to the two connection shafts, the torsion mechanism being configured to provide a damping force in a case that the target support assembly is rotated relative to the support base.

11. The display apparatus according to claim 10, wherein the torsion mechanism comprises a torsion member and an elastic element sleeved on each of the two connection shafts, wherein the torsion member is abutted against a portion, sleeved on the connection shaft, of the drive rod, and the elastic element is disposed on a side, facing away from the drive rod, of the torsion member;
wherein two torsion members sleeved on the two connection shafts are fixedly connected.

12. The display apparatus according to claim 11, wherein a plurality of first abutment portions are arranged on a side facing towards the torsion member of the portion, sleeved on the connection shaft, of the drive rod, and a plurality of second abutment portions are arranged on a side, facing towards the drive rod, of the torsion member.

13. The display apparatus according to claim 11, wherein the torsion mechanism further comprises an auxiliary torsion member sleeved on each of the two connection shafts, wherein the auxiliary torsion member is disposed on a side, facing away from the torsion member, of the drive rod, and the auxiliary torsion member is abutted against the portion, sleeved on the connection shaft, of the drive rod;
wherein two auxiliary torsion members sleeved on the two connection shafts are fixedly connected.

14. The display apparatus according to claim 13, wherein the support base is provided with a first limit plate and a second limit plate opposite to each other, and two ends of the connection shaft respectively are connected to the first limit plate and the second limit plate, the auxiliary torsion member, the drive rod, the torsion member, and the elastic element are sequentially arranged between the first limit plate and the second limit plate, and an end, facing away from the torsion member, of the elastic element is abutted against the second limit plate.

15. The display apparatus according to claim 2, wherein the hinge further comprises a protective member movably connected to a side, facing away from the flexible display panel, of the support base, wherein the protective member is used to cover at least a portion of the flip assembly, is slidably connected to the body support assembly and the rotatable support assembly, and is configured to move along a direction away from the support base during switching of the display apparatus from an unfolded state to a folded state, and to move along a direction close to the support base during switching of the display apparatus from folded state to the unfolded state.

16. The display apparatus according to claim 15, wherein the target support assembly comprises a support portion and a second connection block, wherein the second connection block is fixedly connected to a side, facing away from the flexible display panel, of the support portion, and a second arc-shaped chute is arranged in a side of the second connection block; and
the protective member comprises a protective plate, an extension portion secured to a side, facing towards the support base, of the protective plate, and a rotating plate fixedly connected to a side, facing away from the protective plate, of the extension portion, wherein a second protrusion portion matched with the second arc-shaped chute is arranged on the rotating plate, and the second protrusion portion is slidably connected to the second connection block within the second arc-shaped chute.

17. The display apparatus according to claim 16, wherein the target support assembly comprises two second connection blocks, wherein the rotating plate is disposed between the two second connection blocks, two second protrusion portions opposite to each other are arranged on the rotating plate, and the two second protrusions portions are respectively disposed in the two second arc-shaped chutes of the two second protrusion blocks.

18. The display apparatus according to claim 16, wherein the protective member further comprises a first guide member fixedly connected to a side, facing away from the protective plate, of the extension portion, and a second guide member is arranged on a side, facing towards the protective plate, of the support base;
wherein a blind hole is arranged in one of the first guide member and the second guide member, and another of the first guide member and the second guide member is capable of extending into the blind hole and is capable of sliding within the blind hole.

19. The display apparatus according to claim 2, wherein the hinge further comprises two protective side plates connected to two ends of the support base, wherein the support base is disposed between the two protective side plates in the second direction; and
an avoidance groove matched with the protective side plates is arranged in a side surface of the target support assembly.

20. A wearable device, comprising: a display apparatus and a watchband detachably connected to the display apparatus, wherein the display apparatus comprises:
a body support assembly;
two rotatable support assemblies disposed on two sides of the body support assembly in a first direction;
a hinge disposed between the body support assembly and the rotatable support assembly in the first direction, wherein the hinge comprises a support base and at least two flip assemblies, wherein the support base extends along a second direction intersected with the first direction; and the at least two flip assemblies are oppositely disposed in the first direction and are both connected to the support base, one of the at least two flip assemblies is connected to the body support assembly, and another of the at least two flip assemblies is connected to the rotatable support assembly; and
a flexible display panel, wherein a rear surface of the flexible display panel is connected to the body support assembly, the support base, and the rotatable support assemblies.
